(19) United States
(12) Patent Application Publication
(10) Pub. No.: US 2016/0293837 A1
(43) Pub. Date: Oct. 6, 2016

(54) MULTILAYER HARD MASK PATTERNING FOR FABRICATING INTEGRATED CIRCUITS

(71) Applicant: Rongfu Xiao, Dublin, CA (US)

(72) Inventor: Rongfu Xiao, Dublin, CA (US)

(73) Assignee: Shanghai CiYu Information Technologies Co., LTD, Shanghai (CN)

(21) Appl. No.: 14/675,746

(22) Filed: Apr. 1, 2015

(51) Int. Cl. H01L 43/12; H01L 43/02; H01L 43/08

(52) U.S. Cl. CPC H01L 43/12; H01L 43/08; H01L 43/02

(57) ABSTRACT

A composite hard mask is disclosed that helps formation of an integrated circuit (IC), for example, a magnetic random access memory (MRAM) cell with ultra-small lateral dimension, especially 65 nm or finer ones. The hard mask element contains a heavy metal Ta layer and carbon layer atop the Ta. The IC or MRAM device pattern is first transferred from photoresist to carbon layer by ashing using gas(es) comprising oxygen, and then to heavy metal Ta layer using gas(es) comprising Fluorine. Alternatively, A dielectric layer selected from SiO2, SiN, SiON or SiC can be added atop the C layer to form a tri-layer hard mask element. By adding a thin dielectric layer above the carbon layer, the etching selectivity between photoresist and carbon layer can be further improved. Such a hard mask element is particularly needed for ultra-fine lithography including 193 nm lithography in which photoresist is thin and not sufficient to prevent a Ta layer from being etched away before a good hard mask is completely formed.

### BACKGROUND OF THE INVENTION

1. Field of the Invention

This invention relates generally to patterning using hard mask elements for fabricating an integrated circuit (IC), for example, a magnetic-random-access memory (MRAM), with ultra-fine 193 nm or finer photolithograpy.

2. Description of the Related Art

In recent years, magnetic random access memories (hereinafter referred to as MRAMs) using the magnetoresistive effect of ferromagnetic tunnel junctions (also called MTJs) have been drawing increasing attention as the next-generation solid-state nonvolatile memories that can cope with high-speed reading and writing, large capacities, and low-power-consumption operations. A ferromagnetic tunnel junction has a three-layer stack structure formed by stacking a recording layer having a changeable magnetization direction, an insulating spacing layer, and a fixed layer that is located on the opposite side from the recording layer and maintains a predetermined magnetization direction.

To record information in such magnetoresistive elements, there has been suggested a write method using spin momentum transfers or spin torque transfer (STT) switching technique, or the so-called STT-MRAM. Depending on the direction of magnetic polarization, STT-MRAM is further clarified as in-plane STT-MRAM and perpendicular pSTT-MRAM, among which pSTT-MRAM is preferred. According to this method, the magnetization direction of a recording layer is reversed by applying a spin-polarized current to a magnetoresistive element. Furthermore, as the volume of the magnetic layer forming the recording layer is reduced, the injected spin-polarized current to write or switch can be also smaller. Accordingly, this method is expected to be a write method that can achieve both device miniaturization and currents reduction.

In the mean time, since the switching current requirements reduce with decreasing MTJ element dimensions, pSTT-MRAM has the potential to scale nicely at the most advanced technology nodes. Thus, it is desirable to pattern pSTT-MRAM elements into ultra small dimensions having a good uniformity and minimum impact on MTJ magnetic properties by a manufacturing method that realizes high yield, highly-accurate reading, highly-reliable recording and low power consumption while suppressing destruction and reduction of life of MTJ memory device due to recording in a nonvolatile memory that performs recording based on resistance changes, and maintaining a high thermal factor for a good data retention.

However, patterning a small MTJ element may lead to increasing variability in MTJ resistance and sustaining relatively high switching current or recording voltage variation in a pSTT-MRAM; accordingly a degradation of MRAM performance would occur. In the current MRAM fabrication process, a heavy metal such as Ta is deposited on top of a MTJ stack, and acts both as a hard mask for the etching of the MTJ stack and as a conduction channel to the top electrode. Fabrication of MTJ cell with dimensions of 65 nm or less requires 193 nm or finer lithography which limits photoresist layer thickness to less than 1500 Angstroms. However, a thin photoresist layer requires a thin Ta hard mask layer to guarantee that the hard mask pattern will be completely formed before the photoresist mask is consumed during an etch transfer step. Thus, on one hand, the thickness of a Ta layer should be sufficient to allow a complete etching of MRAM film stack. On the other hand, the Ta layer should not be too thick since a thicker photoresist mask will be required for pattern transfer, and as the photoresist thickness increases there is a greater tendency for the photoresist pattern to collapse which drives more rework and higher cost. Unfortunately, a thin Ta hard mask leads to potential issues of electrical shorting as mentioned previously and limits the amount of etch time available to transfer the hard mask pattern through the MTJ stack of layers because the hard mask erodes during the pattern transfer process. Thus, other alternatives besides a simple Ta hard mask are necessary when fabricating MTJ cell beyond 65 nm.

To overcome the shortcoming of single layer Ta hard mask as mentioned above, it has been reported that, as shown in FIG. 1A, patterning of a MTJ 110 sitting atop a bottom electrode BE 100 can use a bi-layer hard mask element consisting of a first hard mask layer of Ta 120 and a second hard mask layer of SiO2 or SiN 135 atop the Ta [U.S. Pat. No. 8,722,543]. Unfortunately, for a 193 nm or finer lithography, there is not enough photoresist 150 and anti-reflection layer (ARL) 140 to protect SiO2 or SiN 135 from being exposed before the Ta layer 120 is completely etched. As shown in FIG. 1B, the SiO2 dielectric 135 hard mask element is almost completely etched away before the Ta layer 120 is completely over etched. Thus it is difficult to form sharp edged walls of Ta 120 mask, resulting in an ill-defined hard mask for underneath MTJ patterning.

On the other hand, in semiconductor industry for DRAM fabrication, an amorphous carbon layer has been widely used as hard mask for dielectric deep trench etch, in which the carbon layer is first etched by oxygen ashing and then the patterned carbon is used as a hard mask for subsequent dielectric etch [for example, see, ECS Transactions, 35 (4) 701-716 (2011)] resulting well defined deep trenches/vias.

### BRIEF SUMMARY OF THE PRESENT INVENTION

For improving the fineness and precision of IC patterning so as the density and yield of fabricated IC a composite hard mask is disclosed that helps formation of an IC, for example, an MRAM cell with ultra-small dimension <65 nm. A hard mask element has a bi-layer of heavy metal Tatalum (Ta) and ashable carbon (C) atop or atri-layer of Ta, C, and dielectric silicon dioxide (SiO2) or silicon nitride (SiN) successively atop one after another.

An MRAM device pattern is first transferred from a photoresist mask to the adjacent carbon layer that is atop the Ta layer by ashing using gas(es) containing oxygen, and then to heavy metal Ta layer using gas(es) containing Fluorine.

Alternatively, by adding a thin dielectric layer, preferably SiO2 or SiN layer, above the carbon layer as an etching enhancement layer (EEL), the etching selectivity between the photoresist mask and the carbon layer can be further improved. Such a hard mask element (HME) is particularly needed for 193 nm or finer lithography in which a photoresist mask is thin and not sufficient to prevent a Ta layer from being etched away before a good hard mask is formed.

The following detailed descriptions are merely illustrative in nature and are not intended to limit the embodiments of the subject matter or the application and uses of such embodiments. Any implementation described herein as exemplary is not necessarily to be construed as preferred or advantageous over other implementations. Furthermore, there is no intention to be bound by any expressed or implied theory presented in the preceding technical field, background, brief summary, or the following detailed description.

### BRIEF DESCRIPTION OF THE DRAWINGS

FIG. 1A illustrates a prior art having a bi-layer (Ta/SiO2) hard mask for MRAM patterning before etching.

FIG. 1B illustrates a prior art having a bi-layer (Ta/SiO2) hard mask after hard mask etching.

FIG. 2A illustrates first embodiment of present invention having a Ta/C hard mask for MRAM patterning before etching.

FIG. 2B illustrates first embodiment of present invention having a C mask after etching for transferring a PR mask to a C layer.

FIG. 2C illustrates first embodiment of present invention having a Ta mask after etching for transferring a C mask to a Ta layer.

FIG. 2D illustrates first embodiment of present invention having an MRAM fabricated after etching using a patterned Ta mask.

FIG. 3A illustrates second embodiment of present invention having a Ta/C/EEL hard mask for MRAM patterning before etching, wherein the EEL is made of one or more of Si oxide (SiO2), Si nitride (SiN), Si oxynitride (SiON), and Si carbide (SiC).

FIG. 3B illustrates second embodiment of present invention having the EEL mask after etching for transferring a PR mask to the EEL layer.

FIG. 3C illustrates second embodiment of present invention having the mask of C after etching for transferring an EEL mask to the C layer.

FIG. 3D illustrates second embodiment of present invention having the mask of Ta after etching for transferring a mask of C to the Ta layer.

FIG. 3E illustrates second embodiment of present invention having an MRAM fabricated after etching using a patterned mask of Ta.

FIG. 4 illustrates third embodiment of present invention having a tri-layer PRE of ARL/IPML/PRL and a bi-layer Ta/C hard mask for MRAM patterning before etching.

FIG. 5 illustrates forth embodiment of present invention having a bi-layer PRE of ARL/PRL and tri-layer HME of Ta/C/EEL for MRAM patterning before etching.

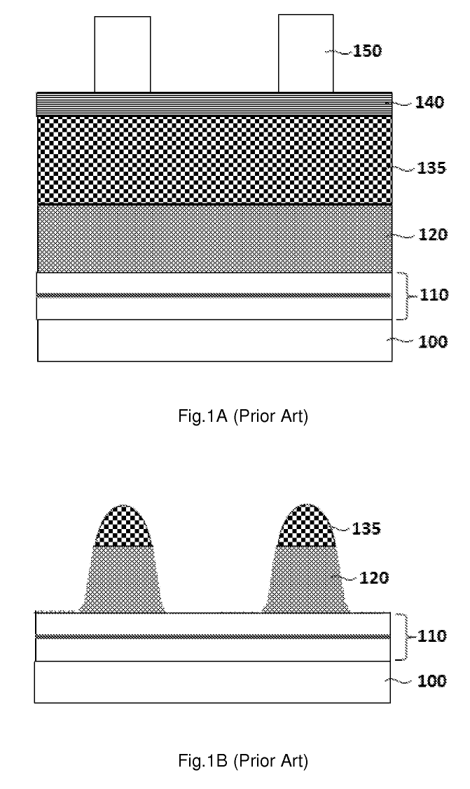

Table 1 illustrates etching rate for the materials discussed in this invention using CF4 and O2 gas, respectively.

### DETAILED DESCRIPTION OF THE INVENTION

A method of fabricating an integrated circuit (IC) including but not limited to a magnetic random access memory (MRAM), in any possible process order or sequence as long as producing the same or similar product or apparatus as in a preferred process order or sequence as below, comprising
forming an IC film element (IC-FE) or MRAM film element (MRAM-FE);
forming a hard mask element (HME) atop the IC-FE or MRAM-FE;
forming a photoresist element (PRE) atop the HME;
patterning the PRE by photolithography or in-print;
patterning the HME;
patterning the IC-FE or MRAM-FE; and
encapsulating the IC-FE or MRAM-FE by a Silicon nitride (SiN) layer.
   The method in present invention is in general suitable for IC fabrication patterning. However, herein, as an example, it is illustrated in MRAM fabrication patterning.

An exemplary embodiment will be described hereinafter with reference to the accompanying drawings. The drawings are schematic or conceptual, and the relationships between the thickness and width of portions, the proportional coefficients of sizes among portions, etc., are not necessarily the same as the actual values thereof.

### Embodiment One

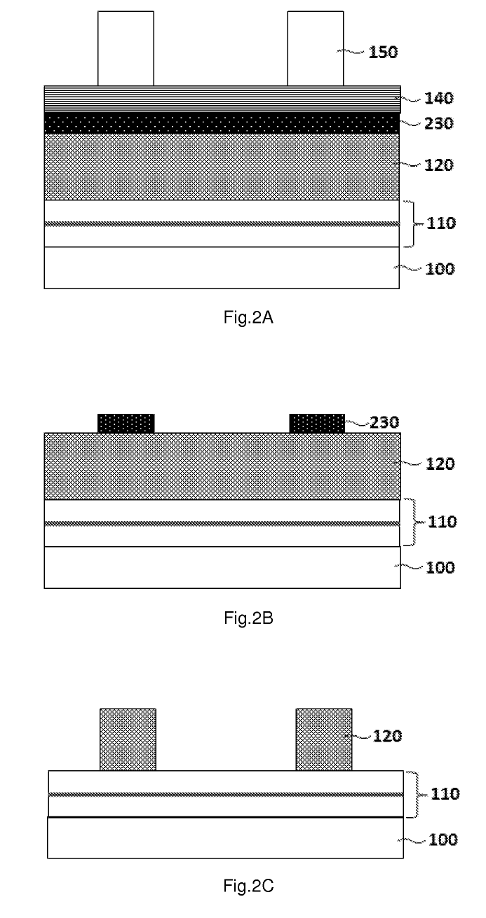

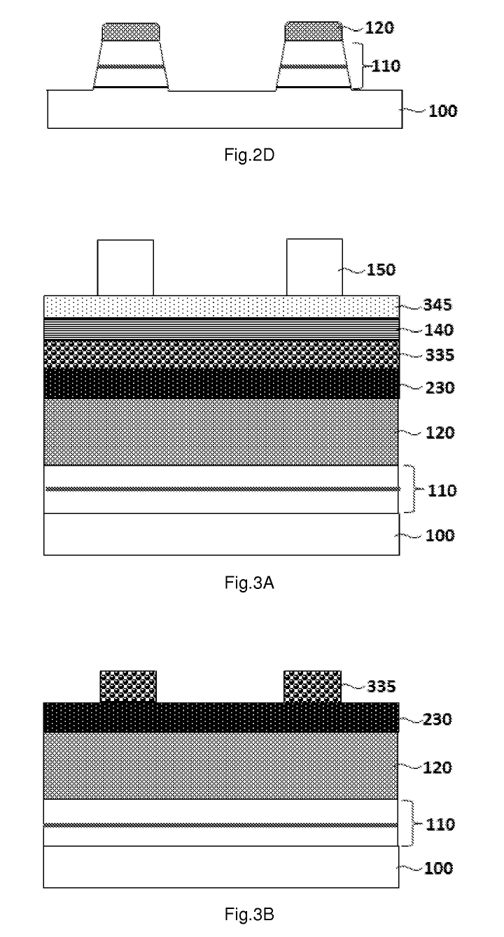

Though there are various sequences of making the product, in FIG. 2A, it is preferred that having an MRAM film element (MRAM-FE) 110 atop a bottom electrode (BE) base layer 100 made first, wherein a set of required films stacked one by one for forming a functional foundation of MRAM before an MRAM circuit is fabricated. A step forming a hard mask element (HME) 120/230 starts with forming a metal Ta layer 120 with a preferred thickness between 50-150 nm followed by forming a carbon layer 230 with a preferred thickness between 20 -200 nm atop the Ta layer 120. The Ta layer 120 may be formed by approaches including physical sputtering, or ion-beam deposition using Ta as a target. The carbon layer 230 is formed by approaches including one or more of the following methods a). chemical vapor deposition using reactants comprising C, H, and O; b). a spin-on-Carbon coating; c). physical sputtering deposition using carbon as a target; and d). ion-beam deposition using carbon as a target. Then an antireflection layer (ARL) 140 and a photoresist layer (PRL) 150 are formed by spin-coating atop of the carbon layer of HME thus forming a bi-layer photoresist element (PRE) atop the HME.

Next, the PRL 150 is patterned, as shown in FIG. 2A, either by photolithography with the help of ARL or in-print with a mask mold followed by patterning the ARL 140 with etching. Thus, the bi-layer PRE is patterned. Then using patterned PRE as a mask, the carbon layer 230 of HME is patterned, as shown in FIG. 2B, by O2, O2+Ar, or O2+CF4+Ar ashing. Then the Ta layer 120 of the HME is patterned, as shown in FIG. 2C, by reactive ion etching (RIE) with gases comprising CF4 or a mixture of CF4, C, F, and H, using the patterned carbon 230 as a hard mask followed by ashing the remained carbon layer 230 atop the Ta layer 120 of HME by O2. Next, the MRAM film element (MRAM-FE) 110 atop 100 is patterned by etching using gases containing methanol (CH3OH), ethanol (C2H5OH), a mixture of CO and NH4, or Chlorine (Cl) as etchant(s), using the patterned Ta layer 120 as a hard mask. Then, if it is necessary and condition permits, a process of ion beam trimming using Ar, or Ar and O₂ gases is employed to remove a thin layer from the wall-edges which could be damaged during RIE of MRAM cell. Thus, magnetically isolated MRAM cells are formed, as shown in FIG. 2D, above the BE 100.

### Embodiment Two

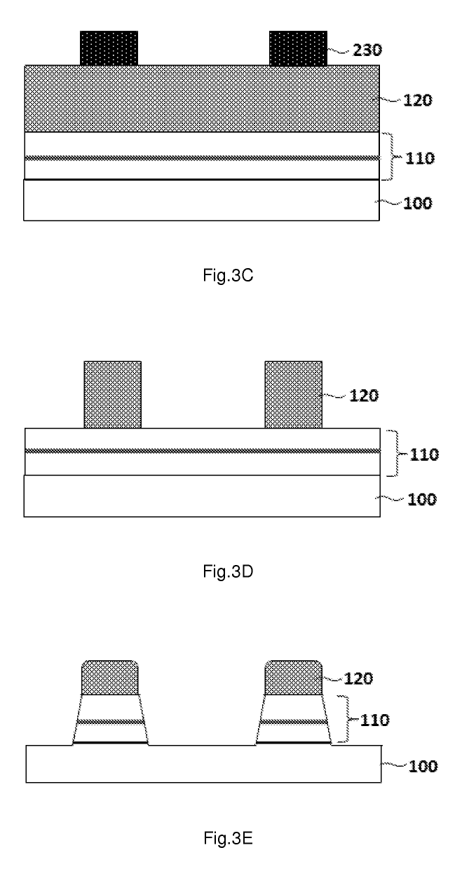

As another example, alternatively illustrating the method in present invention, as shown in FIG. 3A, an MRAM film element (MRAM-FE) 110 atop 100 is made first, wherein a set of required films stacked one by one for forming a functional foundation of MRAM before an MRAM circuit is fabricated. A step forming a hard mask element (HME) starts with forming a metal Ta layer 120 with a preferred thickness between 50-150 nm followed by forming a carbon 230 with a preferred thickness between 20-200 nm atop the Ta layer 120, that is formed by approaches including physical sputtering, or ion-beam deposition using Ta as a target. The next step is forming an etching enhancement layer (EEL) 335 made of one or more of Si oxide (SiO2), Si nitride (SiN), Si oxynitride (SiON), and Si carbide (SiC), atop the carbon layer 230, with a preferred thickness of 50-200 nm. The SiO2 layer of the EEL 335 in HME is formed by approaches including one or more of the following: a). chemical vapor deposition using reactants comprising Si, H, and O; b). spin-on-SiO coating; c). physical sputtering deposition using Si or SiO2 as a target with Ar or Ar+O2 gas(es); and d). ion beam deposition using SiO2 as a target. The SiN layer of the EEL 335 in the HME is formed by approaches including one or more of the following: a). chemical vapor deposition using reactants comprising Si, N, and H; and b). physical sputtering deposition using Si as a target with Ar+N2 or Ar+NH4 gases. The SiON layer of EEL 335 in the HME is formed by approaches including one or more of the following: a). chemical vapor deposition using reactant(s) comprising Si, O, N, and H; and b). physical sputtering deposition, using Si as a target with gases comprising Ar, O, and N. The SiC layer of the EEL 335 in the HME is formed by approaches including one or more of the following: a). chemical vapor deposition using reactants comprising Si, C, and H; b). physical sputtering deposition using SiC as a target; and c). ion beam deposition using SiC as a target. The carbon layer is formed by approaches including one or more of the following: a). chemical vapor deposition using reactants comprising C, H, and O; b). a spin-on-Carbon coating; c). physical sputtering deposition using carbon as a target; and d). ion-beam deposition using carbon as a target. Then an antireflection layer (ARL) 140 is formed atop of carbon layer 230 of the HME followed by forming a photoresist layer (PRL) 150 atop the ARL 140, wherein both the PRL 150 and the ARL 140 may be formed by spin-on-coating. Alternatively, a light polarization manipulation layer (LPML) 345 is formed atop the ARL 140 before forming a PRL thus forming a tri-layer photoresist element (PRE) atop the HME for achieving a better light exposure in the PRL 150, wherein the LPML 345 may also be formed by spin-on-coating.

Next, the PRL 150 is patterned, as shown in FIG. 3A, either by photolithography or in-print with a mold followed by patterning LPML 345 and ARL 140 by etching using the patterned PRL 150 as a mask. Next steps include a). patterning the EEL 335 of the HME by reactive ion etch (RIE) with reactant gas(es) containing CF4 or a mixture of CF4, C, F, and H, using the patterned PRE as a mask, as shown in FIG. 3B; b). patterning the carbon layer 230 of HME by O2, or O2+Ar ashing using the patterned EEL 335 as a hard mask, as shown in FIG. 3C; c). patterning the Ta layer 120 of the HME by RIE with reactant gas(es) containing CF4 or a mixture of CF4, C, F, and H, using the patterned carbon 230 as a hard mask followed by ashing the remained carbon layer 230 atop the Ta layer 120 of HME by O2 as shown in FIG. 3D. Table 1 illustrates etching rate using CF4 gas and ashing rate using O2 gas for each targeted material in the present invention.

Next, using the Ta layer 120 as a hard mark, the MRAM film element (MRAM-FE) is patterned by reactive ion etching (RIE) using reactant gas(es) including one or more of CH3OH, CH5OH, a mixture of CO and NH4, and Chlorine (Cl). Then, if it is necessary and condition permits, a process of ion beam trimming using Ar, or Ar and O2 gases is employed to remove a thin layer from the wall-edges which could be damaged during RIE of MRAM cell. Thus, magnetically isolated MRAM cells, as shown in FIG. 3E, above BE 100, are formed.

Alternatively, the MRAM film element (MRAM-FE) is patterned by ion beam etching (IBE), instead of RIE using Ar, or Ar and O2 gas(es). By tuning the ion-beam power and ion-milling angle, MRAM wall-edges with less damage can be formed.

### Embodiment Three

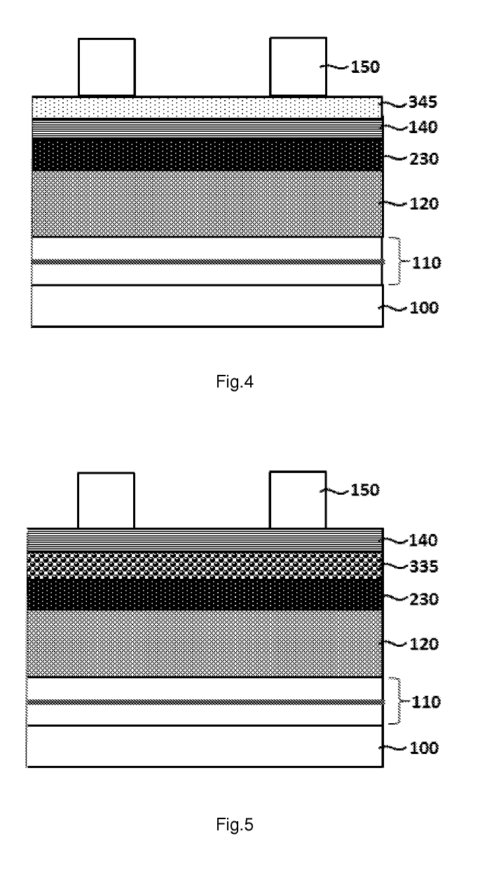

In this embodiment, the process of forming and patterning the PRE in Embodiment Two is used to replace the process of forming and patterning the PRE in Embodiment One. While associated processes may follow accordingly, all other processes remain the same as that in Embodiment One. FIG. 4 shows such a case before HME patterning.

### Embodiment Four

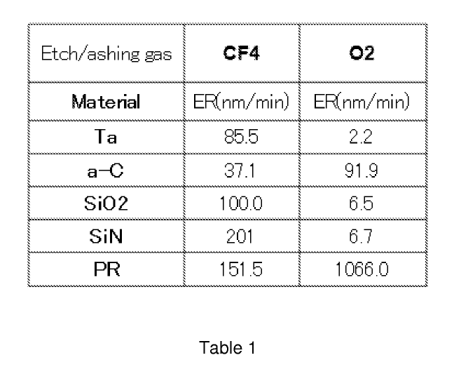

In this embodiment, the process of forming and patterning the HME in Embodiment Two is used to replace the process of forming and patterning the HME in Embodiment One. While associated processes may follow accordingly, all other processes remain the same as that in Embodiment One. FIG. 5 shows such a case before HME patterning.

1. A method of fabricating an integrated circuit (IC) including but not limited to a magnetic random access memory (MRAM) comprising, in any possible process order or sequence as long as producing the same or similar product or apparatus as in a preferred process order or sequence below,
forming an IC film element (IC-FE) or MRAM film element (MRAM-FE);
forming a hard mask element (HME) atop the IC-FE or MRAM-FE;
forming a photoresist element (PRE) atop the HME;
patterning the PRE by photolithography or in-print;
patterning the HME;
patterning the IC-FE or MRAM-FE; and
encapsulating the IC-FE or MRAM-FE by a Si nitride (SiN) layer.

2. The method of claim 1, wherein forming an MRAM-FE comprising
forming a seed layer;
forming a magnetic memory function element (MMFE) atop the seed layer; and
forming a capping layer atop the MMFE.

3. The method of claim 2, wherein forming an MMFE comprising
forming a magnetic memory layer atop the seed layer;
forming a magnetic tunneling layer atop the magnetic memory layer; and
forming a magnetic reference layer atop the tunneling layer.

4. The method of claim 2, wherein forming an MMFE, alternatively, comprising
forming a magnetic reference layer atop the seed layer;
forming a magnetic tunneling layer atop the magnetic reference layer; and
forming a magnetic memory layer atop the tunneling layer.

5. The method of claim 1, wherein forming an HME comprising
forming a Ta layer atop the IC-FE or MRAM-FE, with a preferred thickness between 50-150 nm; and
forming a carbon layer atop the Ta layer, with a preferred thickness between 20-200 nm.

6. The method of claim 5, wherein forming a carbon layer in HME comprising one or more of the following approaches:
a). employing chemical vapor deposition using reactants comprising C, H, and O;
b). employing a spin-on-Carbon layer;
c). employing physical sputtering deposition using carbon as a target; and
d). employing ion-beam deposition using carbon as a target.

7. The method of claim 1, wherein forming an HME, alternatively, comprising
forming a Ta layer atop the IC-FE or MRAM-FE, with a preferred thickness between 50-150 nm;
forming a carbon layer atop the Ta layer, with a preferred thickness between 20-200 nm; and
forming an etching enhancement layer (EEL) comprising one or more of Si oxide (SiO2), Si nitride (SiN), Si oxynitride (SiON), and Si carbide (SiC), atop the carbon layer, with a preferred thickness between 20-200 nm.

8. The method of claim 7, wherein forming a SiO2 layer in the EEL comprising one or more of:
a). employing chemical vapor deposition using reactants comprising Si, H, and O;
b). employing a layer comprising spin-on-SiO;
c). employing physical sputtering deposition using Si or SiO2 as a target with Ar or Ar+O2 gases; and
d). employing ion beam deposition using SiO2 as a target.

9. The method of claim 7, wherein forming a SiN layer in the EEL comprising one or more of approach(es):
a). employing chemical vapor deposition using reactants comprising Si, N, and H; and
b). employing physical sputtering deposition using Si as a target with Ar+N2 or Ar+NH4 gases.

10. The method of claim 7, wherein forming a SiON layer in the EEL comprising one or more of approach(es):
a). employing chemical vapor deposition using reactant(s) comprising Si, O, N, and H; and
b). employing physical sputtering deposition using Si as a target with gases comprising Ar, O, and N.

11. The method of claim 7, wherein forming a SiC layer in the EEL comprising one or more of approaches:
a). employing chemical vapor deposition using reactants comprising Si, C, and H;
b). employing physical sputtering deposition using SiC as a target; and
c). employing ion beam deposition using SiC as a target.

12. The method of claim 1, forming a PRE comprising
forming an antireflection layer (ARL) atop the HME;
forming a photoresist layer (PRL) atop the ARL; and
patterning the PRL and ARL thus patterning the PRE.

13. The method of claim 1, forming a PRE, alternatively, comprising
forming an antireflection layer (ARL) atop the HME;
forming a light polarization manipulation layer (LPML) atop the ARL;
forming a PRL atop the LPML; and
patterning the PRL, LPML, and ARL thus patterning the PRE.

14. The method of claim 1, wherein patterning an HME comprising
patterning the carbon layer of the HME by ashing with gas(es) comprising one or more of O2, O2+Ar, and O2+CF4+Ar, using the patterned PRE as a mask;
patterning the Ta layer of the HME by reactive ion etching (RIE) with gas(es) comprising one or both of CF4 and a mixture of CF4, C, F, and H, using the patterned carbon as a hard mask; and
ashing the remained carbon layer atop the Ta layer of HME by O2.

15. The method of claim 1, wherein patterning an HME, alternatively, if the HMEE comprises an EEL of one or more of Si oxide (SiO2), Si nitride (SiN), SiON, and SiC for an enhanced etching result in addition to a Ta layer and a carbon layer, comprising
patterning the layer comprising one or more of SiO2, SiN, SiON and SiC of the HME by RIE with gas(es) comprising one or both of CF4 and a mixture of CF4, C, F, and H, using the patterned PRE as a mask;
patterning the carbon layer of HME by O2, or O2+Ar ashing using the patterned SiO2, SiN, SiON or SiC as hard mask;
patterning the Ta layer of HME by RIE with gas(es) comprising one or both of CF4 and a mixture of CF4, C, F, and H, using the patterned carbon as a hard mask; and
ashing the remained carbon layer atop the Ta layer of HME by O2.

16. The method of claim 1, wherein patterning an IC-FE or MRAM-FE comprising etching IC-FE or MRAM-FE by RIE with gas(es) comprising one or more of methanol (CH3OH), ethanol (C2H5OH), a mixture of CO and NH4, and Chlorine (Cl), using the patterned Ta layer as a hard mask.

17. The method of claim 16, wherein the patterned IC-FE or MRAM-FE by RIE is further trimmed by ion-beam etching (IBE) for achieving improved wall-edges of cells within the patterned IC-FE or MRAM-FE if it is necessary and condition permits.

18. The method of claim 1, wherein patterning an IC-FE or MRAM-FE, alternatively, comprising etching IC-FE or MRAM-FE by IBE, using the patterned Ta layer as a hard mask.
